(19) United States
(12) Patent Application Publication
(10) Pub. No.: US 2006/0221718 A1
(43) Pub. Date: Oct. 5, 2006

(54) Memory module and memory system having data protection function, and method for controlling the memory module

(75) Inventor: Nobuhiro Ono, Kanagawa (JP)

Correspondence Address: C. IRVIN MCCLELLAND;OBLON, SPIVAK, MCCLELLAND, MAIER & NEUSTADT, P.C., 1940 DUKE STREET, ALEXANDRIA, VA, 22314, US

(73) Assignee: Kabushiki Kaisha Toshiba, Minato-ku (JP)

(21) Appl. No.: 11/373,117

(22) Filed: Mar. 13, 2006

(30) Foreign Application Priority Data
Mar. 14, 2005 (JP) 2005-071482

(51) Int. Cl. G11C 7/10

(52) U.S. Cl. 365/189.04

(57) ABSTRACT

A memory module includes a memory unit, a mode register configured to store a mode identifier, a mode memory configured to store mode information including a keyhole mode ID and an access attribute, a memory I/F unit configured to receive a key mode ID, and an access permission unit configured to permit access to the memory unit according to the access attribute when the key mode ID and the keyhole mode ID, corresponding to the mode identifier, are the same.

### CROSS REFERENCE TO RELATED APPLICATIONS AND INCORPORATION BY REFERENCE

This application is based upon and claims the benefit of priority from prior Japanese Patent Application P2005-071482 filed on Mar. 14, 2005; the entire contents of which are incorporated by reference herein.

### BACKGROUND OF THE INVENTION

1. Field of the Invention

The present invention relates to a nonvolatile memory module and a nonvolatile memory system having a data protection function, and a method for controlling the nonvolatile memory module.

2. Description of the Related Art

Recently, a large number of apparatuses using a nonvolatile memory, which stores a large amount of data, have appeared on the market due to rapid development of the information society. Since a nonvolatile memory retains stored data even after the power supply is shutdown, a large amount of data stored in the nonvolatile memory is always available. Therefore, even if the data stored in the nonvolatile memory is required to be kept confidential, unauthorized reading of the data from the nonvolatile memory and falsification thereof is possible. Accordingly, there is a requirement to ensure confidentiality of the data stored in the nonvolatile memory.

### SUMMARY OF THE INVENTION

An aspect of the present invention inheres in a memory module. The memory module includes a memory unit; a mode register configured to store a mode identifier; a mode memory configured to store mode information including a keyhole mode ID and an access attribute; a memory I/F unit configured to receive a key mode ID; and an access permission unit configured to permit access to the memory unit according to the access attribute when the key mode ID and the keyhole mode ID, which corresponds to the mode identifier, are the same.

Another aspect of the present invention inheres in a memory system. The memory system includes a memory module; an access mode memory configured to store the mode information stored in the mode memory; and a processor configured to access the memory module while referencing the mode information stored in the access mode memory. The memory module includes a memory unit; a mode register configured to store a mode identifier; a mode memory configured to store mode information including a keyhole mode ID and an access attribute; a memory I/F unit configured to receive a key mode ID; and an access permission unit configured to permit access to the memory unit according to the access attribute when the key mode ID and the keyhole mode ID, which corresponds to the mode identifier, are the same.

Still another aspect of the present invention inheres in a method for accessing a memory module including a memory unit. The method includes storing a mode identifier in a mode register; storing mode information including a keyhole mode ID and an access attribute in a mode memory; entering a key mode ID in a memory I/F unit; and permitting access to the memory unit according to the access attribute when the key mode ID and the keyhole mode ID, which corresponds to the mode identifier, are the same.

### BRIEF DESCRIPTION OF THE DRAWINGS

FIG. 1 is a schematic diagram showing a memory module according to a first embodiment of the present invention;

FIG. 2 shows an exemplary mode information stored in a mode memory according to the first embodiment of the present invention;

FIG. 3 shows an exemplary configuration of a memory constituting the mode memory according to the first embodiment of the present invention;

FIG. 4 shows a sequence diagram explaining a method for powering on the memory module according to the first embodiment of the present invention;

FIG. 5 is a sequence diagram explaining a method for registering information in the mode memory according to the first embodiment of the present invention;

FIG. 6 is a flowchart explaining a method for registering information in the mode memory according to the first embodiment of the present invention;

FIG. 7 is a sequence diagram explaining a method for mode switching according to the first embodiment of the present invention;

FIG. 8 is a flowchart explaining a method for mode switching according to the first embodiment of the present invention;

FIG. 9 is a sequence diagram explaining a method for accessing a memory unit according to the first embodiment of the present invention;

FIG. 10 is a flowchart explaining a method for accessing a memory unit according to the first embodiment of the present invention;

FIG. 11 is a schematic diagram showing a memory system according to a second embodiment of the present invention;

### DETAILED DESCRIPTION OF THE INVENTION

Various embodiments of the present invention will be described with reference to the accompanying drawings. It is to be noted that the same or similar reference numerals are applied to the same or similar parts and elements throughout the drawings, and the description of the same or similar parts and elements will be omitted or simplified.

In the following descriptions, numerous specific details are set forth such as specific signal values, etc., to provide a thorough understanding of the present invention. However, it will be obvious to those skilled in the art that the present invention may be practiced without such specific details. In other instances, well-known circuits have been shown in block diagram form in order not to obscure the present invention in unnecessary detail.

A nonvolatile memory retains stored data as long as the data is not explicitly erased. Even if the data stored in the nonvolatile memory is required to be kept confidential, unauthorized reading of the data from the nonvolatile memory and falsification thereof is possible.

Setting up a password-based authentication procedure in nonvolatile memory systems that includes a nonvolatile memory to restrict access to the nonvolatile memory is possible. However, in a case where nonvolatile memory modules, including a nonvolatile memory, are removed from the nonvolatile memory systems and the nonvolatile memory modules are directly accessed, confidentiality of data is not guaranteed by setting up an authentication procedure in the nonvolatile memory systems. In order to enhance confidentiality of data, a method of incorporating nonvolatile memory modules with an authentication circuit configured based on passwords unique to the respective nonvolatile memory modules at the time of access is possible. However, such a method fails to ensure a high level of confidentiality due to the following problems.

(1) There is a risk of passwords being analyzed due to multiple verification of the password.

(2) In the case where passwords are leaked, unauthorized access to the nonvolatile memory modules cannot be prevented.

(3) When an access method of allowing access to all regions of a nonvolatile memory after password authentication is completed is adopted, the convenience of guest users being able to use the memory, which is provided by preparing accessible regions before password authentication, is restricted.

### First Embodiment

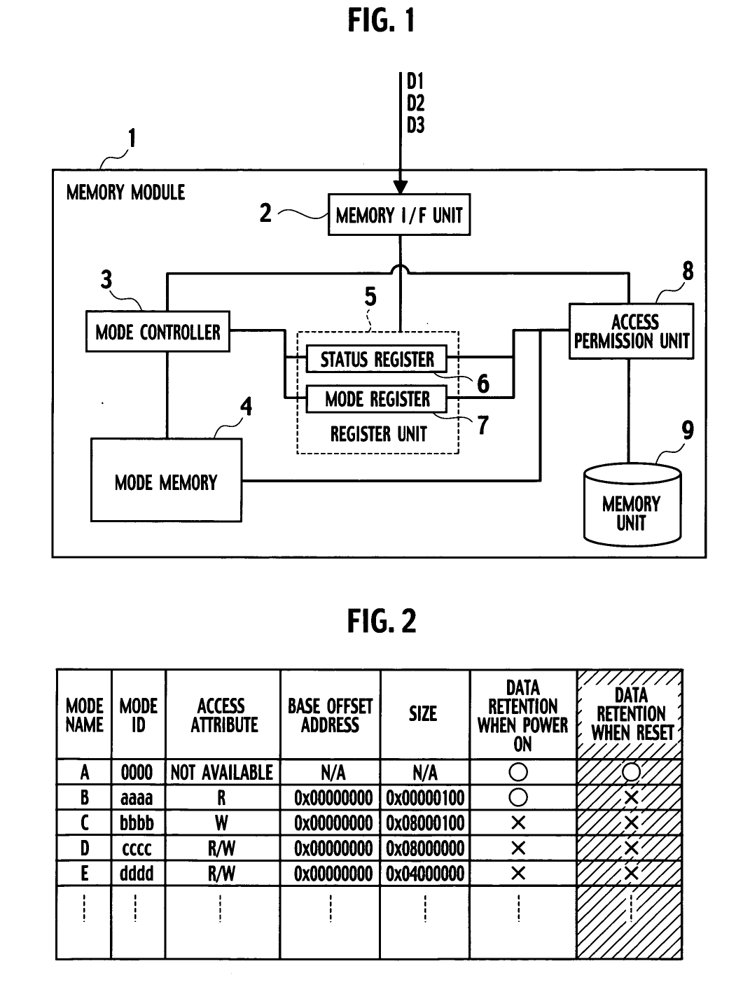

As shown in FIG. 1, a memory module 1 according to a first embodiment includes a memory interface (I/F) unit 2, a mode controller 3, a mode memory 4, a register unit 5, an access permission unit 8, and a memory unit 9. The register unit 5 includes a status register 6 and a mode register 7.

An external processor or the like can access the memory unit 9 via the memory I/F unit 2 of the memory module 1. The memory I/F unit 2 includes an access acceptance mechanism providing access to the memory unit 9.

The mode memory 4 stores various types of mode information for controlling access to the memory unit 9. The mode memory 4 is closed. As used herein, ‘closed’ means the contents of the mode memory 4 cannot be accessed from the outside of the memory module 1 via only the memory I/F unit 2.

The mode register 7 stores mode information, such as a mode name or a mode ID, as a mode identifier for allowing access to the memory unit 9 at the time of accessing the memory module 1. Hereafter, the access mode that permits access to the memory unit 9, at the time of accessing the memory module 1, is referred to as the ‘access mode of the memory module 1’.

The mode controller 3 controls the mode memory 4 so that the mode memory 4 registers mode information. The mode controller 3 controls the mode register 7 so that the mode register 7 registers an access mode of the memory module 1.

The access permission unit 8 controls access to the memory module 1 by retrieving from the mode register 7 and the mode memory 4 the mode information of the memory module 1 at the time of access thereto.

The status register 6 stores status information indicating current status of the memory module 1. The status information is stored in the status register 6 as a flag status, for example.

The memory unit 9 is a nonvolatile memory. A nonvolatile memory that is accessible in the same manner as a dynamic random access memory (DRAM) may be employed. More specifically, a ferroelectric memory such as a ferroelectric random access memory (FeRAM) may be employed as the nonvolatile memory.

Details of each functional block of the memory module 1 are described forthwith.

<Mode Memory 4>

As shown in FIG. 2, the mode memory 4 has column headings: ‘mode name’, ‘mode ID’, ‘access attribute’, ‘base offset address’, ‘size’, ‘data retention when power on’, and ‘data retention when reset’. Tables of all configurations enabling specification of mode attributes other than the combination of column headings shown in FIG. 2 are naturally included within the scope of the first embodiment. The mode information stored in the mode memory 4 can only be changed by the control of the mode controller 3 and can only be referenced by the access permission unit 8. The mode information stored in the mode memory 4 is can not be referenced by the memory I/F unit 2. This procedure closes the mode memory 4 to the outside of the memory module 1, i.e., the mode memory 4 can not be accessed from outside of the memory module 1. Mode information for each access mode is constituted by ‘mode name’, ‘mode ID’, ‘access attribute’, ‘base offset address’, ‘size’, ‘data retention when power on’, and ‘data retention when reset’. Closing the mode memory 4 also closes the mode information stored in the mode memory 4. The mode information is correlated to a mode name and then stored in the mode memory 4. For example, a mode ID for an access mode of the mode name may be extracted from the mode memory 4 using the mode name.

The ‘mode name’ is used for a mode identifier for an access mode. With the mode memory 4, the mode information corresponding to the access mode of the specified mode name is extracted from all mode information stored in the mode memory 4. By having the mode ID function as a mode name identifier the heading ‘mode name’ can be omitted from the mode memory 4.

The ‘mode ID’ is information entered in the mode-switch acceptance mechanism of the memory I/F unit 2. The mode ID is used as a password for accepting mode switching as well as a mode ID for the access mode of the memory module 1 after mode switching. There are several registration methods and handling methods for restricting registration of the mode ID to the mode memory 4. For example, the mode information of a mode ID first hit when referencing the mode memory 4 after registration of the same mode ID has been regarded as mode information, or registration of the same mode ID to the mode memory 4 is not permitted. Use of any method for registering mode IDs to the mode memory 4 is permitted as long as it guarantees selection of a set of pairs of mode information or specified separate elements of mode information in the mode memory 4 in conformity with the specification of a mode ID. The mode ID registered in the mode memory 4 is refereed to as the ‘keyhole mode ID’.

The ‘access attribute’ is information specifying an access method or combination of access methods for the memory unit 9, such as read data (R), write data (W), or both read and write data (R/W).

The ‘base offset address’ specifies the base address of a memory area in the memory unit 9 as a target for access control. With the first embodiment, an offset address from the first address of the memory is a base offset address.

The ‘size’ specifies the size of a memory area in the memory unit 9, which is a target for access control.

An identifier, which specifies whether or not to retain data corresponding to the access mode that has been set at the time of initializing the mode memory 4, when the power of the memory module 1 is on, is set to ‘data retention when power on’ The mode memory 4 basically discards and deletes mode information when the power of the memory module 1 is on. Thus, an ‘X’ identifier is set to the heading ‘data retention when power on’ as shown in FIG. 2. Deleting the mode information when the power is on and initializing the mode memory 4 can keep the access method for the memory unit 9 confidential. As exceptions, the mode information of the default mode and mode information of the access mode where a ‘circle’ identifier is set to the heading ‘data retention when power on’ are not discarded from the mode memory 4 when the power is on. The default mode is set in the first row of the mode memory shown in FIG. 2 where all normal access is denied. The access mode where a ‘circle’ identifier is set to the heading ‘data retention when power on’ specifies data retention when the power is on.

An identifier, which indicates whether or not it is in the access mode to retain data when the mode controller 3 requests resetting of the mode memory 4, is set to ‘data retention when reset’. The information of ‘data retention when reset’ can not be changed. In the default mode, the ‘circle’ identifier specifying data retention is always set as an identifier to require data retention when the mode memory 4 is reset. With the other registered access modes, ‘X’ indicators represent no data retention when the mode memory 4 is reset, and are always set as indicators for ‘data retention when reset’.

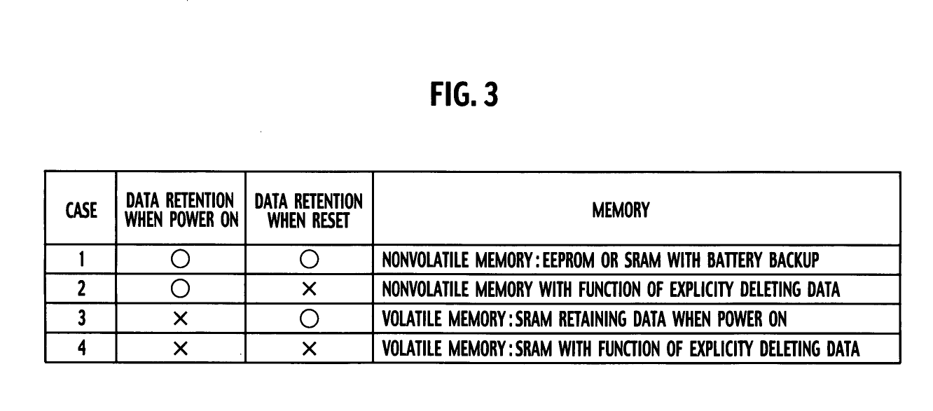

FIG. 3 shows an exemplary configuration of a memory constituting the mode memory 4. FIG. 3 shows an example where the mode memory 4 is set according to the following case 1 through case 4. When in the default mode of case 1 where a ‘circle’ identifier indicates data retention when the power is on and also indicates data retention when the mode memory 4 is reset, mode information of the default mode is stored in a nonvolatile memory. The nonvolatile memory in case 1 is, for example, an electrically erasable and programmable ROM (EEPROM), SRAM with battery backup, or the like. When in the access mode of case 2 where a ‘circle’ identifier indicates data retention when the power is on while ‘X’ identifier indicates data retention when the mode memory 4 is reset, mode information of the access mode is stored in a nonvolatile memory unit. The nonvolatile memory in case 2 includes a function of explicitly deleting the mode information when the mode memory 4 is reset. When in the access mode of case 3 where ‘X’ identifier indicates data retention when the power is on while a ‘circle’ identifier indicates data retention when the mode memory 4 is reset, mode information of the access mode is stored in a nonvolatile memory. The nonvolatile memory in case 3 is a device, such as SRAM, retaining data when the power is on. When in the access mode of case 4 where ‘X’ identifier indicates data retention when the power is on and also indicates data retention when the mode memory 4 is reset, mode information of the access mode is stored in a volatile memory such as SRAM. The volatile memory employed in case 4 includes a function of explicitly deleting the mode information when the mode memory 4 is reset. The memory providing the mode memory 4 is not limited to the combinations of the above-mentioned case 1 through case 4, and may be modified to encompass a memory having other characteristics within the scope of the fist embodiment. Alternatively, not only can the mode memory 4 be provided by a single memory, but also the mode memory 4 may be provided by memories including the memory unit 9, the mode register 7, and the status register 6 and are must naturally be included within the scope of the first embodiment.

<Mode Register 7>

The mode register 7 stores mode information as a mode identifier for the access mode of the memory module 1. With the first embodiment, the mode register 7 is described as a register storing mode names as a mode identifier. However, mode information may naturally be stored in the mode register using various methods. For example, mode information other than mode names, such as mode attributes, is stored in the mode register 7 as additional information, or line numbers of the mode memory 4 are stored in the mode register 7 without using the mode name. In other words, the mode register 7 stores information uniquely identifying the access mode. Furthermore, information indicating the status of the mode memory 4 may also be stored in the mode register 7.

<Memory I/F Unit 2>

When the memory module 1 is accessed, the memory I/F unit 2 determines the propriety of an access to the memory module 1, based of the status information stored in the status register 6, and transmits a mode change notification or access notification to other functional blocks, such as the mode controller 3 and the access permission unit 8. The ‘mode change notification’ is transmitted from the memory I/F unit 2 to the mode controller 3 when switching the access mode of the memory module 1, as described later. Access to the memory module 1 includes normal access D1, information reference access D2, and special access D3.

‘Normal access D1’ refers to reading or writing at specified addresses in the memory unit 9. ‘Information reference access D2’ refers to an access for instructing the status information in the status register 6 and to access to a mode name or related information in the mode register 7. ‘Special access D3’ refers to access for instructing information mode registration and initialization of the mode memory 4 and the like.

While the memory I/F unit 2 should have a signal line allowing the same access as access to a general static random access memory (SRAM), for example, it is not so limited in the first embodiment, and a signal line group allowing access, other than access to a SRAM, may be provided.

The access permission unit 8 determines whether an access to the memory unit 9 is permitted. When access to the memory unit 9 is not permitted, a notification of the prohibition of the attempted access is transmitted to the memory I/F unit 2 from the access permission unit 8. There are various notification methods suitable for various functional block implementing methods, such as a dedicated signal line to output a notification to from the memory module 1 or having the status register 6 storing the status information be accessed from outside of the memory module 1, the notifying methods are not so limited in the first embodiment. Reasons for which access to the memory unit 9 is not allowed may include an access error or the like occurring within the memory unit 9. To identify a reason for denial of access, a notification to the effect that the access is not permitted is sent to the memory I/F unit 2 from the access permission unit 8. When a notification to the effect that access is not permitted is sent, the reason for denial of access may be verified by referring to the status information in the status register 6.

The memory I/F unit 2 has a mode information registration acceptance mechanism and a mode-switch acceptance mechanism corresponding to the special access D3, aside from the normal access acceptance mechanism corresponding to the normal access D1.

In the case where there is a normal access D1 to the memory module 1 in a different operating environment than the normal operating environment, such a higher power supply voltage than normal to the memory module 1, or in the case where there is access to the memory module 1 in a special access sequence, the mode information registration acceptance mechanism accepts the access to the memory module 1 as a special access D3 for registering the mode information. An access sequence, which allows the mode information registration acceptance mechanism to accept access to the memory module 1 as the special access D3 for registering the mode information, is hereafter referred to as ‘registration sequence’. Specification for the mode information registration acceptance mechanism to accept the special access D3 may be unique for every memory module 1. The specification for allowing the special access D3 may be of any kind as long as it is difficult for an unauthorized person to decipher it to access the memory unit 9. A registration sequence of providing variable consecutive attribute data of the access mode information after applying a higher voltage to a signal line than when normally accessing the memory module 1 and provision of a special command to a specific address, for example, is set as a specification for the registration acceptance mechanism to accept the special access D3. The registration sequence is secret information and is not revealed to a person who is not permitted to access memory unit 9.

Closing the mode information registration acceptance method and inhibiting mode information registration acceptance in the operating environment at the time of normal access may ensure confidentiality against unauthorized access.

A method of switching the access mode of the memory module 1 is described forthwith. When the memory module 1 is accessed in a special access sequence, the mode-switch acceptance mechanism sends a mode change notification to the mode controller 3. An access sequence, which allows the mode-switch acceptance mechanism to accept access to the memory module 1 as the special access D3 for switching the access mode, is hereafter referred to as ‘mode-switch sequence’. When the mode controller 3 receives the mode change notification, the mode controller 3 changes the mode identifier stored in the mode register 7 to an identifier, which is registered in the mode memory 4, specified by the access in the mode-switch sequence. As a result, the access mode of the memory module 1 is switched. A method of accessing the memory module 1 for switching the access mode may be set to each memory module 1 as a specification for a mode-switch sequence. For example, while watching a signal line prepared for mode switching, an access sequence of providing a certain address with a mode ID for the switched access mode may be considered as a specification for the mode switching method. A detailed description of the specification for the mode switching method is omitted. The memory I/F unit 2 naturally has a mechanism including a signal line for accepting the mode-switch sequence. The mode-switch sequence is secret information and is not revealed to a person who is not permitted to access the memory unit 9.

When the special access D3 is an unauthorized access, status information indicating a denial of access status denying all access to the memory module 1 until the memory module 1 is reset by the mode controller 8 may be stored in the status register 6, or the memory I/F unit 2 may return a dummy response. Here, an ‘unauthorized access’ is a special access D3 conducted in an erroneous access sequence, an access deviating from an access regarding as the special access D3, an access to request switching to the access mode corresponding to a mode ID not registered in the mode memory 4 at the time of mode switching, or the like.

The memory I/F unit 2 returning a dummy reply is intended to complicate determination of whether the operation of the memory module 1 has been completed normally, or whether an unauthorized access has been detected and thus the operation has not been completed normally. For example, in the case where mode switching using a mode ID not stored in the mode memory 4 is requested (detection of unauthorized operation at this time) and reading of the resulting data is requested, the memory I/F unit 2 outputs dummy data as if it were normal response data, such as data of all logical values ‘1’.

<Mode Controller 3>

The mode controller 3 controls the mode register 7 and the mode memory 4 according to notification from the memory I/F unit 2 in order to change the contents of the mode register 7 and the mode memory 4. The status information stored in the status register 6 is set as ‘mode control BUSY’ while the mode controller 3 is processing, in order to verify start and end of processing of the mode controller 3.

The timing for changing mode information stored in the mode register 7 is notified to the mode controller 3 from the memory I/F unit 2. There are three kinds of notifications for changing mode information stored in the mode register 7: (1) initialization notification, (2) special access notification, and (3) mode-switch notification. With the initialization notification and the special access notification, the mode register 7 is set so as to enter an authentication waiting mode after the change of mode information process is completed. ‘Authentication waiting mode’ is an access attribute for not permitting access, which is set as the default mode in the mode memory 4. Operations of the memory module 1 for the three respective notifications are described below.

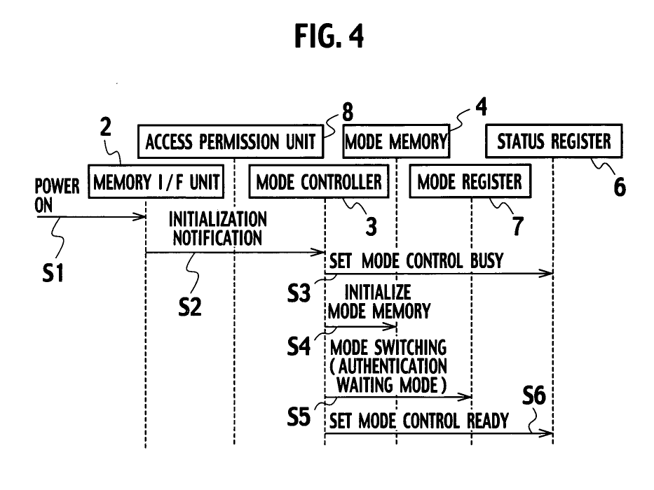

The initialization notification is described by referring to the sequence diagram shown in FIG. 4, the sequence diagram is for when the power of the memory module 1 is on. The initialization notification is sent to the mode controller 3 along with an operation to power on the memory module 1. In step S1 shown in FIG. 4, when the system including the memory module 1 or a person turns on the power of the memory module 1, a power ON signal is entered in the memory I/F unit 2.

In step S2, the memory I/F unit 2 transmits the initialization notification to the mode controller 3.

In step S3, the mode controller 3 sets the status information stored in the status register 6 to ‘mode control BUSY’.

In step S4, the mode controller 3 initializes the mode memory 4. For example, in the mode memory 4 shown in FIG. 2, mode information data corresponding a mode name ‘C’ to a mode name ‘E’, which have ‘X’ identifiers for retaining data when power is on, are deleted.

In step S5, the mode controller 3 switches the mode stored in the mode register 7 to the default mode of the authentication waiting mode. More specifically, the mode register 7 stores a mode name ‘A’ or a mode ID ‘0000’ of FIG. 2.

In step S6, the mode controller 3 sets the status information stored in the status register 6 to ‘mode control READY’. This concludes the operation of the memory module 1 when power is turned on.

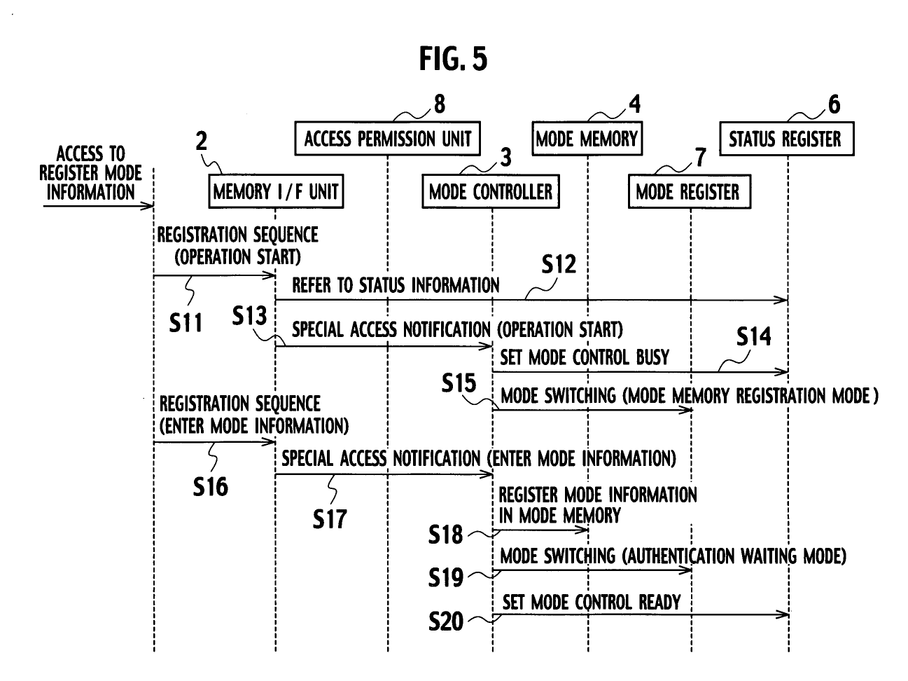

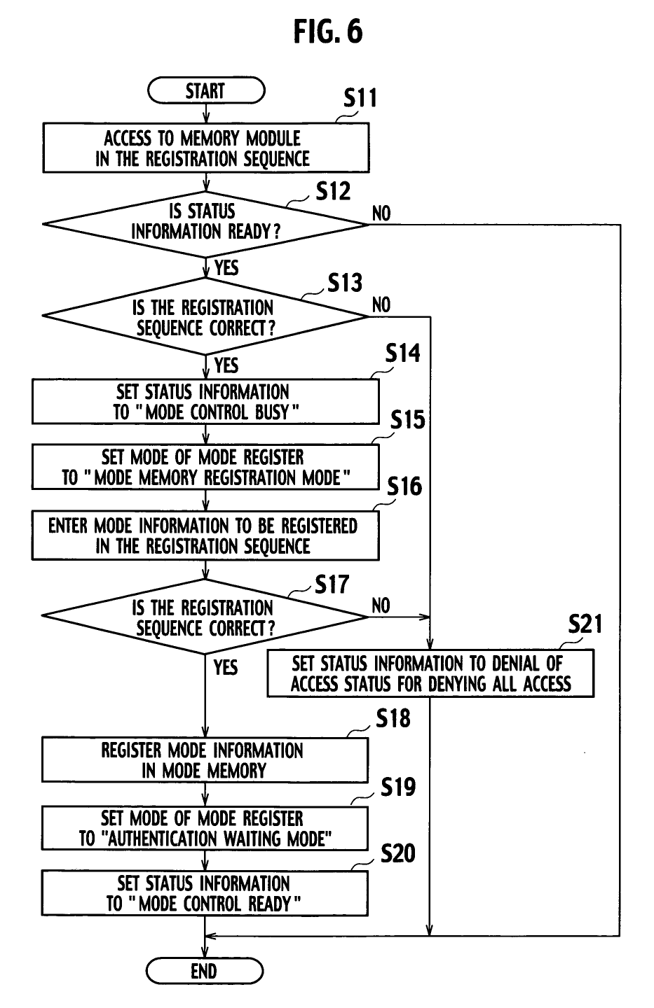

The special access notification is described by referring to the sequence diagram shown in FIG. 5 and the flowchart shown in FIG. 6. The special access notification is sent along with the operation, which is for registering mode information in the mode memory 4. In the case where the system including the memory module 1 or a person registers a mode information, in step S11 shown in FIG. 5 and FIG. 6, the memory I/F unit 2 is accessed in a secret registration sequence to start an operation for registering the mode information.

In step S12, the memory I/F unit 2 refers to the status information stored in the status register 6 so as to determine whether the status of the memory module 1 is a READY status, BUSY status, or denial of access status. The memory module 1 proceeds to step S13 when in the READY status. When the memory module 1 is in the BUSY status or the denial of access status, mode information registration is cancelled.

In step S13, the memory I/F unit 2 determines whether the registration sequence is a correct sequence. If the access sequence is correct, the memory I/F unit 2 transmits the special access notification to the mode controller 3 and proceeds to step S14. If the access sequence is incorrect, processing proceeds to step S21.

In step S14, the mode controller 3 sets the status information stored in the status register 6 to ‘mode control BUSY’.

In step S15, the mode controller 3 sets the mode stored in the mode register 7 to ‘mode memory registration mode’.

In step S16, the mode information to be registered in the secret registration sequence is entered in the memory I/F unit 2.

In step S17, the memory I/F unit 2 determines whether the mode information is entered in the correct registration sequence. When the mode information is entered in the correct access sequence, the memory I/F unit 2 transmits the special access notification to the mode controller 3 and processing proceeds to step S18. When the mode information is entered in an incorrect access sequence, processing proceeds to step S21.

In step S21, the mode controller 3 sets the status information stored in the status register 6 to the denial of access status for denying all access to the memory I/F unit 2 from outside of the memory module 1. The operation for registering the mode information in the mode memory 4 is concluded.

In step S18, the mode controller 3 controls the mode memory 4 so that the mode memory 4 stores the mode information authorized to be registered.

In step S19, the mode controller 3 sets the mode stored in the mode register 7 to the authentication waiting mode.

In step S20, the mode controller 3 sets the status information stored in the status register 6 to ‘mode control READY’. This concludes the setting operation for the mode memory 4.

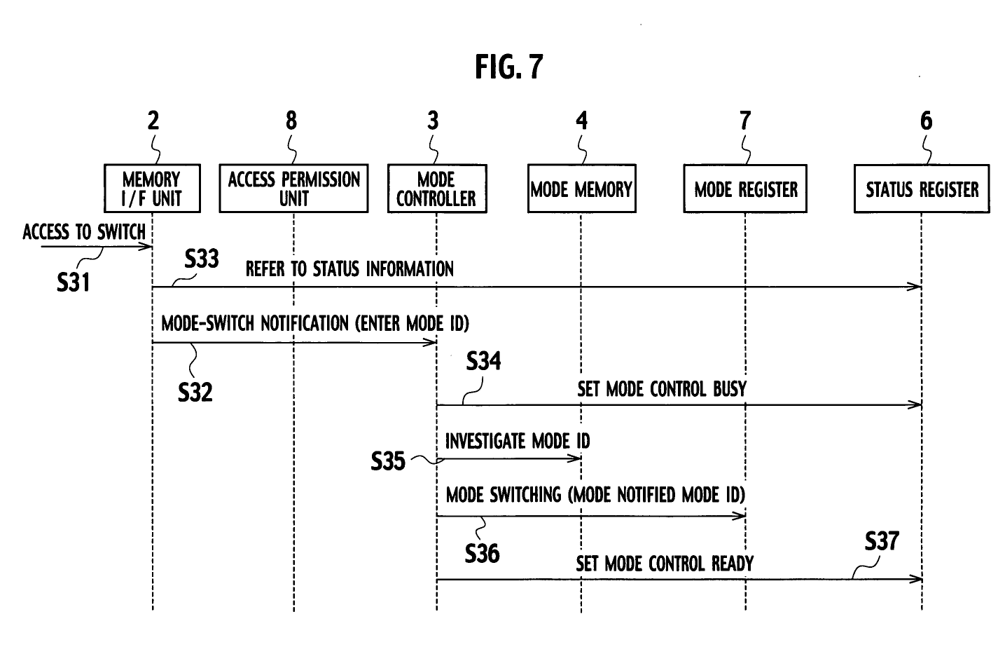

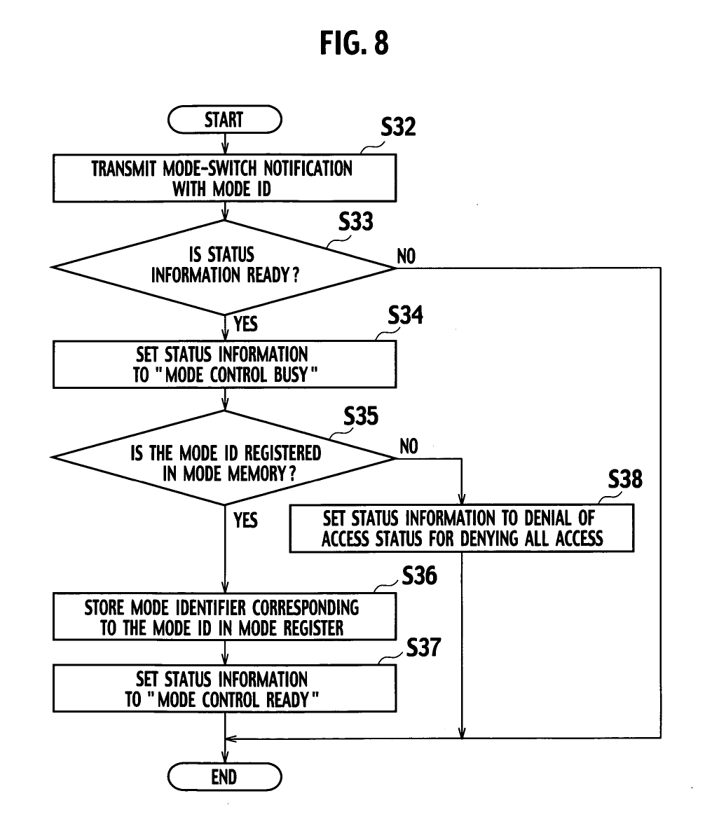

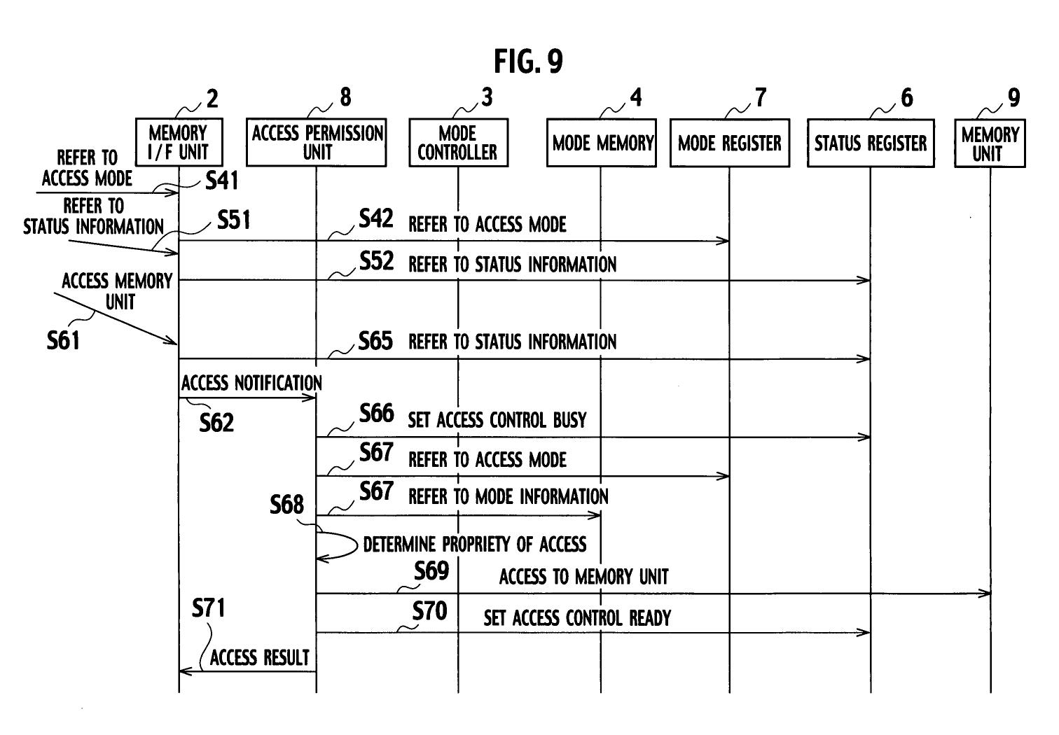

The mode-switch notification is described by referring to the diagram shown in FIG. 7 and the flowchart shown in FIG. 8. The mode switch notification is set along with a mode-switching operation for the memory module 1. When the system including the memory module 1 or a person carries out mode switching of the memory module 1, in step S31 of FIG. 7, the mode ID of the access mode to be switched is entered in the memory I/F unit 2 in a mode-switch sequence.

In step S32, the memory I/F 2 transmits the mode-switch notification with the mode ID to the mode controller 3.

In step S33, the memory I/F unit 2 refers to the status information stored in the status register 6 to determine whether the status information is a READY status, control BUSY status, or denial of access status. Processing proceeds to step S34 when the status information is a READY status. When the status information is a BUSY status or denial of access status, the mode-switching operation is cancelled.

In step S34, the mode controller 3 sets the status information stored in the status register 6 to ‘mode control BUSY’.

In step S35, the mode controller 3 investigates whether or not the mode ID for the access mode, after notification of mode switching from the memory I/F unit 2, is registered in the mode memory 4. Processing proceeds to step S36 if the mode ID for the access mode, after mode switching is registered in the mode memory 4. Otherwise, if the mode ID for the access mode after mode switching is not registered in the mode memory 4, processing proceeds to step S38.

In step S38, the mode controller 3 sets the status information stored in the status register 6 to the denial of access status for denying all access to the memory I/F unit 2 from outside of the memory module 1. The operation for when switching the mode of the memory module 1 is concluded.

In step S36, the mode controller 3 controls the mode register 7 so that the mode register 7 stores a mode identifier such as a mode name, which identifies an access mode corresponding to the notified mode ID, in the mode register 7.

In step S37, the mode controller 3 sets the status information stored in the status register 6 to ‘mode control READY’. This concludes the mode-switching operation of the memory module 1.

<Access Permission Unit 8>

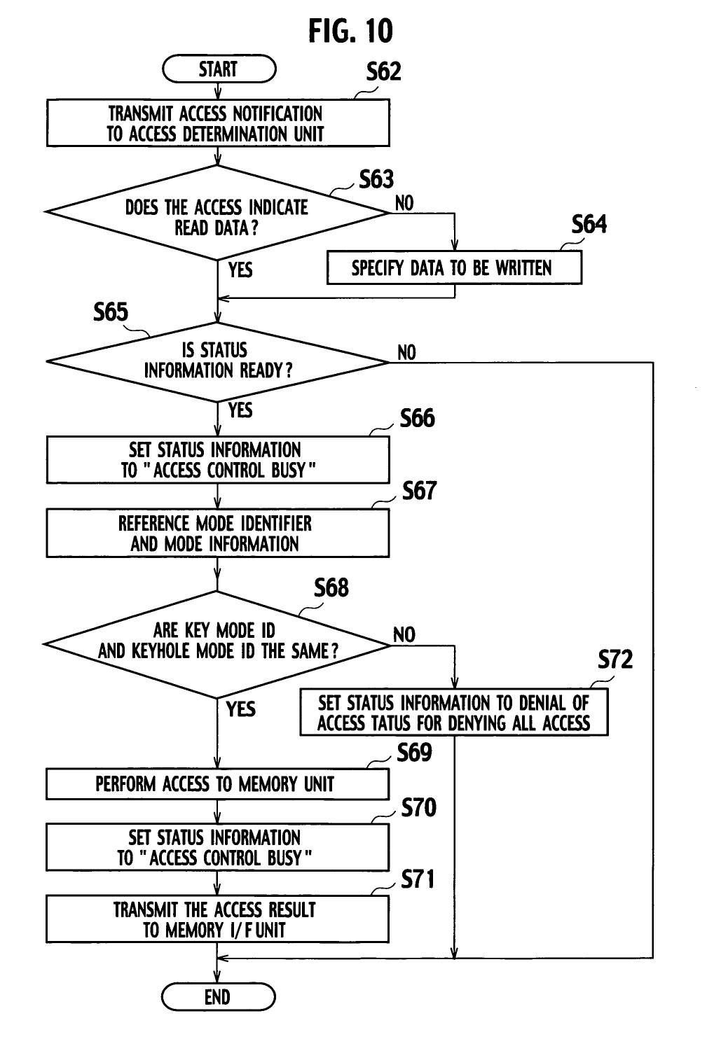

Operations of the memory module 1 related to the access permission unit 8 are described by referring to the diagram shown in FIG. 9 and the flowchart shown in FIG. 10.

The mode identifier for the access mode of the memory module 1, stored in the mode register 7, may be referenced before the access to the memory unit 9. In the case where the system including the memory module 1 or a person verifies the access mode of the memory module 1, an information reference access D2 is entered in the memory I/F unit 2 in step S41 of FIG. 9. In step S42, the memory I/F unit 2 referees to the mode identifier for the access mode of the memory module 1 stored in the mode register 7, and transfers the referenced mode identifier for the access mode to the outside of the memory module 1.

Furthermore, the status information stored in the status register 6 may be referenced before the access to the memory unit 9. In the case where the system including the memory module 1 or a person verifies the status information of the memory module 1, the information reference access D2 is entered in the memory I/F unit 2 in step S51 of FIG. 9. In step S52, the memory I/F unit 2 referees to the status information stored in the status register 6, and outputs the referenced status information to the outside of the memory module 1.

In the case where the system including the memory module 1 or a person accesses the memory unit 9, a mode ID, an access attribute, and a base address are entered in the memory I/F unit 2 in step S61 of FIG. 9. The mode ID entered in the memory I/F unit 2 to access the memory unit 9 is refereed to as the ‘key mode ID’.

In step S62 shown in FIG. 9 and FIG. 10, the memory I/F unit 2 transmits an access notification to the access permission unit 8.

In step S63, the memory I/F unit 2 determines whether or not the access attribute indicates read data. Processing proceeds to step S65 if the access attribute indicates read data. Processing proceeds to step S64 if the access attribute does not indicate reading of data.

In step S64, the memory I/F unit 2 specifies data to be written to the memory unit 9.

In step S65, the memory I/F unit 2 referees to the status information stored in the status register 6 to determine whether the status information is a READY status, a BUSY status, or denial of access status. Processing proceeds to step S66 when the status information is the READY status. When the status information is the BUSY status or denial of access status, access to the memory unit 9 is cancelled.

In step S66, the access permission unit 8 sets the status information stored in the status register 6 to ‘access control BUSY’ so as to verify the start and end of the processing of the access permission unit 8.

In step S67, the access permission unit 8 references the mode identifier for an access mode of the memory module 1 stored in the mode register 7, such as the mode name, the mode ID, and the like which identify the access mode of the memory module 1. The access permission unit 8 referees to the mode information stored in the mode memory 4, such as a keyhole mode ID, an access attribute and a base address corresponding to the access mode specified by the mode identifier stored in the mode register 7.

In step S68, the access permission unit 8 determines the propriety of an access to the memory part 9. More specifically, the key mode ID entered in the memory I/F unit 2 and the keyhole mode ID corresponding to the mode identifier stored in the mode register 7 are compared, and the access permission unit 8 permits access when the key mode ID and the keyhole mode ID are the same. In another case, the key mode ID, the access attribute, and the base address and the like, which are entered in the memory I/F unit 2, and the keyhole mode ID, the access attribute, and the base address and the like corresponding to the access mode of the memory module 1 are compared, when the access permission unit 8 permits access when they match, respectively. Processing proceeds to step S69 if the determination of the access permission unit 8 is to permit access, while processing proceeds to step S72 if the determination is to not permit access.

In step S72, the access permission unit 8 sets the status information of the status register 6 to denial of access status for denying all access to the memory module 1. This concludes the access operation for the memory module 1.

In step S69, the requested access to the memory unit 9 is performed according to the access attribute.

In step S70, the access permission unit 8 sets the status information stored in the status register 6 to ‘access control READY’.

In step S71, the access permission unit 8 transmits, to the memory I/F unit 2, a signal of the access results, such as whether the status of read data or written data is normal or abnormal. This concludes the access operation of the memory module 1.

<Status Register 6>

The status register 6 stores current status information of the memory module 1. The status register 6 stores information indicating BUSY/READY status, error, or the like for mode control and access control. Status information, such as access results, normally included in the memory module 1 is also stored. Furthermore, as described with the memory I/F unit 2, the denial of access status may be stored as status information when an authorized access is detected at the time of registering mode information or at the time of mode switching.

The status information stored in the status register 6 is changed by the mode controller 3 and the access permission unit 8, while the memory I/F unit 2 is only allowed access thereto. Needless to say, all information indicating status information stored in the status register 6 need not be accessible from the memory I/F unit 2. For example, a denial of access status flag or the like indicating whether or not an unauthorized access has been detected need not be accessible from the outside of the memory module 1.

As described above, various configurable access modes for access control are registered in the memory module 1 according to the first embodiment of the present invention. A memory controller including the mode controller 3 or the like, which only switches the various access modes through a mode-switching method using mode ID or the like, and which is a part of the mode information stored at the time of registration, provides a memory module 1 capable of concealing arbitrary memory data from all types of access that does not use a proper access sequence.

As such, the memory module 1 having a nonvolatile memory according to the first embodiment of the present invention has a feature of providing a general protection function to protect against inadvertent access and falsification of the memory data.

According to the memory module 1 of the first embodiment, access restriction to the memory area storing secret data may be set after a power supply is shutdown. More specifically, access control is carried out by switching the access mode using a keyhole mode ID registered in the mode memory 4. This is because the data stored in the memory unit 9 cannot be accessed if the secret keyhole mode ID is unknown. Furthermore, since the mode information of the access mode is registered in the mode memory 4 through the special access D3, a secret registration sequence applied to the special access D3 provides a high level of confidentiality.

According to the memory module 1 of the first embodiment, analysis of passwords for unauthorized access is impossible. Even if mode information registering and mode switching are randomly carried out in order to attempt unauthorized access, all access is denied until the power is turned off in the case where there is an improper access sequence.

According to the memory module 1 of the first embodiment, the authentication procedure for access is constantly being changed. Every time power is supplied to the memory module 1, mode information of an access mode stored in the mode memory 4 is deleted, if the mode information does not specify data retention. Therefore, access means for accessing the memory does not exist as long as an access mode is not registered in the mode memory 4. Furthermore, since the contents of the mode memory 4 can be initialized or changed even while the memory module 1 is operating, keyhole mode ID for authentication and access restricted contents may be updated if necessary. Therefore, confidentiality of data stored in memory unit 9 may be improved by frequently updating the keyhole mode ID assigned to permit access.

According to the memory module 1 of the first embodiment, an access restriction target and the access restriction level are arbitrarily specified. Since the contents of the mode memory 4 may be initialized or changed, access restricted contents may be constantly updated. As a result, by setting access restriction to a minimum, confidentiality of data stored in the memory unit 9 may be improved. Since the mode memory 4 can be initialized or changed even while the memory module 1 is operating, the access restricted contents may be updated if necessary. Since the protection function retaining the mode information in the mode memory 4, even after power is supplied, is provided, an arbitrary memory area may be exclusively assigned for reading without losing convenience of memory.

### Second Embodiment

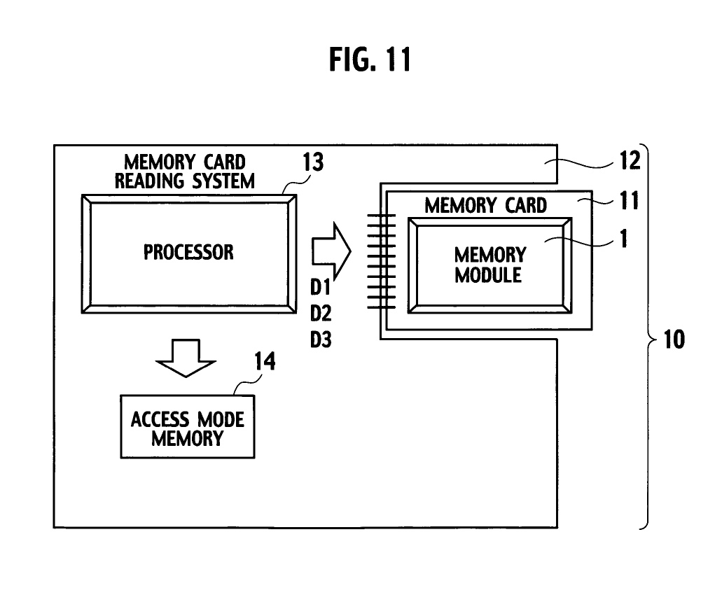

As shown in FIG. 11, a memory system 10 according to a second embodiment has a memory card reading system 12, and a memory card 11 capable of data communication with the memory card reading system 12. The memory card reading system 12 has a processor 13 and an access mode memory 14. The memory card 11 includes the memory module 1 according to the first embodiment. The processor 13 incorporates a logic circuit for executing an access to the memory module 1 in the registration sequence or switch-mode sequence. The processor 13 may be a logic circuit executing the access to the memory module 1 in the registration sequence or switch-mode sequence.

For example, when a specific trigger is entered in the processor 13, access from the processor 13 to the memory module 1 is automatically carried out in the registration sequence. With the memory system 10 shown in FIG. 11, a mechanism for allowing access to the memory module 1 is implemented only by a combination of the processor 13 and the memory module 1.

The access mode memory 14 holds mode information which should be registered in the mode memory 4 shown in FIG. 1. When the memory system 10 is operating, the processor 13 carries out normal access D1, information reference access D2, and special access D3 to the memory card 11 while referencing the mode information of the access mode memory 14. The mode information, such as mode IDs, is correlated with a mode name and stored in the access mode memory 14, as with the mode memory 4 shown in FIG. 2. The access mode memory 14 may be formed in the RAM included in the memory system 10.

In order to ensure confidentiality of the information stored in the access mode memory 14, it is required that the memory area holding the mode information stored in the access mode memory 14 is volatile. If the memory area holding the information stored in the access mode memory 14 is nonvolatile, the memory system 10 is required to consistently delete the mode information stored in the access mode memory 14 when the normal access D1, the information reference access D2, and the special access D3 are not carried out.

An example where the processor 13 accesses the memory module 1 of the memory system 10 shown in FIG. 11 is described forthwith. First, before carrying out the normal access D1 to the memory card 11, the processor 13 carries out the special access D3 to the memory module 1 in the registration sequence. An access mode having mode information, such as the mode ID stored in the access mode memory 14, is registered in the mode memory 4 of the memory module 1 so that the mode information stored in the access mode memory 14 and the mode information stored mode memory 4 are the same.

The processor 13 then begins the normal access D1 to the memory card 11. The processor 13 accesses the memory module 1 in the memory card 11 while referencing the mode information stored in the access mode memory 14. Access from the processor 13 to the memory module 1 is permitted under the condition that the keyhole mode ID included in the mode information accessed by the processor 13 is stored in the mode memory 4.

As described above, the memory system 10 according to the second embodiment of the present invention provides an excellent data protection function against inadvertent access and falsification of data. The remainder of the memory system is effectively the same as the first embodiment, and thus duplicated description thereof is omitted.

Various modifications will become possible for those skilled in the art after receiving the teachings of the present disclosure without departing from the scope thereof.

What is claimed is:

1. A memory module comprising:
a memory unit;
a mode register configured to store a mode identifier;
a mode memory configured to store mode information including a keyhole mode ID and an access attribute;
a memory I/F unit configured to receive a key mode ID; and
an access permission unit configured to permit access to the memory unit according to the access attribute when the key mode ID and the keyhole mode ID, corresponding to the mode identifier, are the same.

2. The memory module of claim 1, further comprising a mode controller configured to control the mode memory so as to delete the mode information stored in the mode memory when power of the memory module is on.

3. The memory module of claim 2, wherein the mode controller further controls the mode memory so as to store the mode information entered in the memory I/F unit in a registration sequence.

4. The memory module of claim 2, wherein the mode controller further controls the mode register so as to store the mode identifier corresponding to the keyhole mode ID entered in the memory I/F unit in a mode-switch sequence.

5. The memory module of claim 1, wherein the mode memory stores a plurality of sets of the mode information.

6. The memory module of claim 1, wherein the memory unit is a nonvolatile memory.

7. The memory module of claim 1, further comprising a status register configured to store status information of the memory module.

8. A memory system comprising:
a memory module comprising:
a memory unit;
a mode register configured to store a mode identifier;
a mode memory configured to store mode information including a keyhole mode ID and an access attribute;
a memory I/F unit configured to receive a key mode ID; and
an access permission unit configured to permit access to the memory unit according to the access attribute when the key mode ID and the keyhole mode ID, corresponding to the mode identifier, are the same;
an access mode memory configured to store the mode information stored in the mode memory; and
an processor configured to access the memory module while referencing the mode information stored in the access mode memory.

9. The memory system of claim 8, wherein the access from the processor to the memory module is permitted when the keyhole mode ID included in the mode information referenced by the processor is stored in the mode memory.

10. The memory system of claim 8, further comprising a mode controller configured to control the mode memory so as to delete the mode information stored in the mode memory when power of the memory module is on.

11. The memory system of claim 10, wherein the mode controller further controls the mode memory so as to store the mode information entered in the memory I/F unit in a registration sequence.

12. The memory system of claim 10, wherein the mode controller further controls the mode register so as to store the mode identifier corresponding to the keyhole mode ID entered in the memory I/F unit in a mode-switch sequence.

13. The memory system of claim 8, wherein the mode memory stores a plurality of sets of the mode information.

14. The memory system of claim 8, wherein the memory unit is a nonvolatile memory.

15. A method for accessing a memory module including a memory unit, comprising:
storing a mode identifier in a mode register;
storing mode information including a keyhole mode ID and an access attribute in a mode memory;
entering a key mode ID in a memory I/F unit; and
permitting access to the memory unit according to the access attribute when the key mode ID and the keyhole mode ID, corresponding to the mode identifier, are the same.

16. The method of claim 15, further comprising:
deleting the mode information stored in the mode memory when power of the memory module is on.

17. The method of claim 15, further comprising:
storing the mode information entered in the memory I/F unit in a registration sequence.

18. The method of claim 15, further comprising:
storing the mode identifier corresponding to the keyhole mode ID entered in the memory I/F unit in a mode-switch sequence.

19. The method of claim 15, further comprising:
transmitting a denial of access notification to the memory I/F unit, when the access to the memory unit is not permitted.

20. The method of claim 15, further comprising:
storing status information, which indicates a denial of access status denying all access to the memory module, in a status register, when an unauthorized access to the memory I/F unit is detected.
